(19) United States
(12) Patent Application Publication
(10) Pub. No.: US 2010/0220265 A1
(43) Pub. Date: Sep. 2, 2010

(54) ILLUMINATION SYSTEM AND DISPLAY DEVICE

(75) Inventors: Johannes Petrus Maria Ansems, Eindhoven (NL); Lars Rene Christian Waumans, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/993,049

(22) PCT Filed: Jun. 20, 2006
(86) PCT No.: PCT/IB2006/051985

§ 371 Date: Dec. 19, 2007

(30) Foreign Application Priority Data
Jun. 23, 2005 (EP) 05105587.9

(51) Int. Cl. G02F 1/1335; H01L 33/52; F21V 9/06; H05B 37/02

(52) U.S. Cl. 349/68; 257/98; 362/228; 362/20; 257/99; 257/E33.059

(57) ABSTRACT

An illumination system comprises a gas discharge lamp (1) and at least one light-emitting diode (2). The illumination system according to the invention comprises means for reducing ultraviolet light emitted by the gas discharge lamp reaching the light-emitting diode. Preferably, the means for reducing ultraviolet light comprises an ultraviolet-absorbing or ultraviolet-reflecting shielding means ( ) provided between the gas discharge lamp and the light-emitting diode. Preferably, the gas-discharge lamp is a fluorescent lamp, for instance, a low-pressure mercury-vapor discharge lamp. Preferably, the illumination system is employed in an emergency lighting device or in a display device, in particular a liquid-crystal display (LCD) device. The illumination system according to the invention has a relatively long life.

### FIELD OF THE INVENTION

The invention relates to an illumination system comprising a gas discharge lamp and at least one light-emitting diode.

The invention also relates to a display device, in particular a liquid-crystal display (LCD) device, comprising such an illumination system.

### BACKGROUND OF THE INVENTION

Illumination systems with a combination of a gas discharge lamp and at least one light-emitting diode are known per se. They are used, inter alia, for so-called ambiance-light applications to adapt ambient light conditions to the mood of a person or persons in a room or to the mood of a TV show or movie shown on a screen at home. The illumination systems are further used in emergency lighting devices and in display devices, such as for instance liquid-crystal display devices.

Generally, gas discharge lamps comprise low-pressure gas discharge lamps and high-pressure gas discharge lamps. In mercury-vapor discharge lamps, mercury constitutes the primary component for the (efficient) generation of ultraviolet (UV) light. A luminescent layer comprising a luminescent material may be present on an inner wall of the discharge vessel to convert UV to other wavelengths, for example, to visible radiation for general illumination purposes. Therefore, such discharge lamps are also referred to as fluorescent lamps. The discharge vessel of low-pressure mercury vapor discharge lamps is usually circular and comprises both elongate and compact embodiments. Normally, means for maintaining a discharge in the discharge space are electrodes arranged in the discharge space. In an alternative embodiment, the low-pressure mercury vapor discharge lamp comprises a so-called electrodeless low-pressure mercury vapor discharge lamp.

Generally, light-emitting diodes (LEDs) can be light sources of distinct primary colors, such as, for example the well-known red, green, or blue light emitters. In addition, the light emitter can have, for example, amber, magenta or cyan as primary color. The primary color can also be a mix of colors or white.

The English Abstract of JP Patent Application JP-A 2003-303501 discloses an emergency lighting device comprising a lamp and at least one light-emitting diode (LED) package. Under normal conditions, the fluorescent lamp or the incandescent lamp is operative. If, however, a power failure occurs, the illumination system switches to a mode of operation where the light-emitting diode operates on a battery package.

A drawback of the known illumination system is that life of the illumination system is limited.

### SUMMARY OF THE INVENTION

The invention has for its object to eliminate the above disadvantage wholly or partly. According to the invention, an illumination system comprising a gas discharge lamp and at least one light-emitting diode, the illumination system comprising means for reducing ultraviolet light emitted by the gas discharge lamp reaching the light-emitting diode.

If in an illumination system the light-emitting diodes (LEDs) are positioned relatively close to the gas discharge lamp, the LEDs experience a relatively high ultraviolet (UV) load, resulting in a relatively rapid decrease in performance of the LEDs, including a reduction in the life of the LEDs. By introducing, according to the invention, means for reducing ultraviolet light in the illumination system between the gas discharge lamp and the LED, the damaging effect of the ultraviolet light emitted by the gas discharge lamp on the LED is reduced.

Preferably, the gas-discharge lamp is a fluorescent lamp. Preferably, the fluorescent lamp is a low-pressure mercury-vapor discharge lamp.

The means for reducing ultraviolet light emitted by the gas discharge lamp reaching the light-emitting diode can be embodied in a variety of manners. To this end a preferred embodiment of the illumination system according to the invention is characterized in that the means for reducing ultraviolet light comprises an ultraviolet-absorbing or ultraviolet-reflecting shielding means provided between the gas discharge lamp and the light-emitting diode. The shielding means can be a UV-absorbing screen between the gas discharge lamp and the LED. Preferably, the UV-absorbing screen is mounted on the LED.

An alternative preferred embodiment of the illumination system according to the invention is characterized in that the means for reducing ultraviolet light comprises an ultraviolet-absorbing material provided on the light-emitting diode and/or on the gas discharge lamp.

The means for reducing ultraviolet light emitted by the gas discharge lamp reaching the light-emitting diode can also be incorporated in the LED. To this end a preferred embodiment of the illumination system according to the invention is characterized in that the light-emitting diode comprises a lens and/or an optoelectronic encapsulant having an improved resistance to ultraviolet light, the means for reducing ultraviolet light being the lens and/or the optoelectronic encapsulant.

In buildings, emergency lighting devices have been installed. An emergency lighting system generally comprises a fluorescent lamp, a ballast and a low-voltage power supply, for instance a battery pack. Under normal conditions, the fluorescent lamp obtains power from the main-power system of the building. When, during an emergency, a main-power failure occurs (e.g. in case of a fire, a fire alarm or other calamity), a low-voltage power supply (battery pack) takes over the power supply and the fluorescent lamp will still burn. In the latter mode of operation also referred to as “emergency mode”, the fluorescent lamp emits light for guiding persons in the building to safe places in case of an emergency situation. If the discharge lamp operates in the emergency mode of operation, the discharge lamp operates on a relatively low current (less then 10% of the nominal current). However, the electrodes in the discharge lamp are not designed for such a low current. This leads to a fast and substantial degradation of electrode material primarily due to sputtering. Such electrode degradation reduces life of the known discharge lamp considerably. This would not be a problem if the emergency light would only be operational during emergency conditions. However, (government) safety regulations require that emergency lighting systems are regularly and frequently tested (typically a least once a month). During testing, the known emergency lighting system is operated for some time in the emergency mode. This frequent testing gives rise to an early failure of the emergency lighting system as compared to normal fluorescent lamp.

The illumination system according to the invention employed as emergency lighting device comprising a gas discharge lamp and at least one LED can be operated in two modes of operation. To this end a preferred embodiment of the illumination system according to the invention is characterized in that the illumination system is in a first mode of operation when the gas discharge lamp is operative and in a second mode of operation when the light-emitting diode is operative. To reduce degradation of the gas discharge lamp while operating in the second mode of operation, a preferred embodiment of the illumination system according to the invention is characterized in that, when a power failure occurs while the illumination system lamp operates in the first mode of operation, a switching means causes the illumination system to operate in the second mode of operation. The switching means detects the power failure in the first mode of operation and causes the start of the second mode of operation. Preferably, the switching means also causes or initiates the disconnection the discharge lamp from the power supply on which the discharge lamp operates in the first mode of operation. Preferably, the light-emitting diode operates on a DC power supply, the DC power supply charging while the illumination system operates in the first mode of operation. Preferably, the DC power supply is a battery.

The illumination system according to the invention employed as backlighting system for display devices, in particular for LCD devices, comprises at least one (low-pressure) mercury vapor discharge lamp and a plurality of LEDs. The LEDs, in particular when LEDs of different primary colors are employed, can be used to change the color and/or the color temperature of the light emitted by the illumination system while the gas discharge lamp has a pre-determined light output. Combining of gas discharge lamps, in particular fluorescent lamps, and LEDs in a backlighting system is particularly advantageous if the fluorescent lamps during operation are employed in a so-called “scanning” mode of operation while the plurality of LEDs, during operation, are used in a continuous mode of operation.

Because the LEDs are well protected against UV emitted by the gas discharge lamps, the illumination systems according to the invention have a relatively long life.

### BRIEF DESCRIPTION OF THE DRAWINGS

These and other aspects of the invention are apparent from and will be elucidated with reference to the embodiments described hereinafter.

In the drawings:

FIG. 1A is a cross-sectional view of a first embodiment of the illumination system according to the invention;

FIG. 1B is a perspective view of a side-emitting light-emitting diode provided an UV shielding means;

FIG. 2 is a cross-sectional view of a second embodiment of the illumination system according to the invention, and

FIG. 3 is a display system.

The Figures are purely diagrammatic and not drawn to scale. Notably, some dimensions are shown in a strongly exaggerated form for the sake of clarity. Similar components in the Figures are denoted as much as possible by the same reference numerals.

### DETAILED DESCRIPTION OF THE PREFERRED EMBODIMENTS

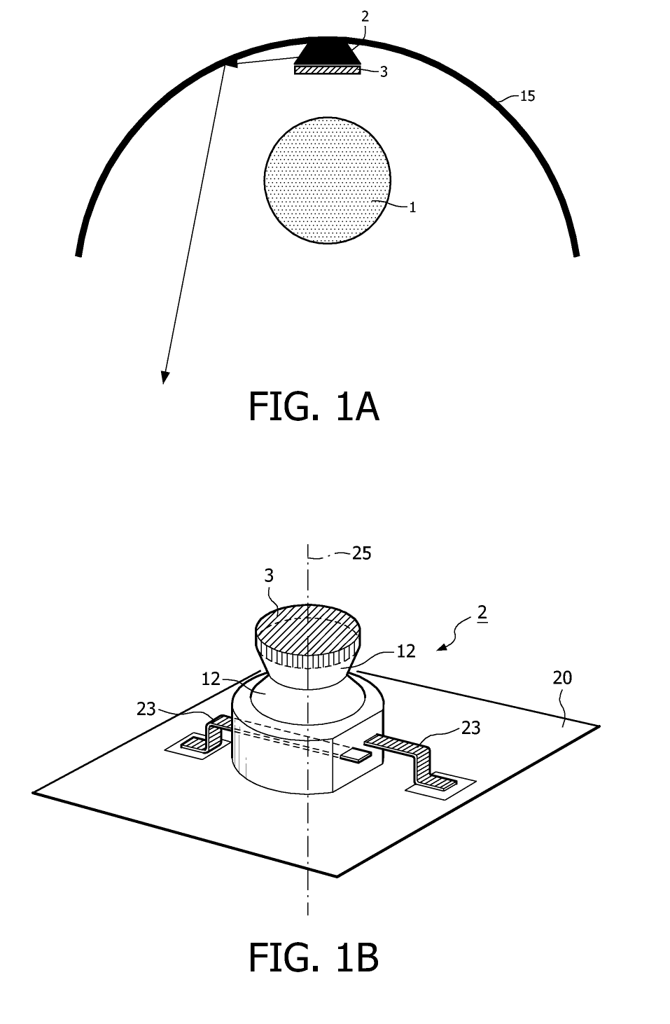

FIG. 1A very schematically shows a cross-sectional view of a first embodiment of the illumination system according to the invention. The illumination system comprises a gas discharge lamp 1 and a light-emitting diode (LED) 2. The illumination system of FIG. 1a further comprises a reflector 15 for directing the light emission by the gas discharge lamp and the LED (see the arrow in FIG. 1A). In the example of FIG. 1A, the LED 2 is a so-called side-emitting LED (see FIG. 1B). According to the invention, the illumination system comprises means for reducing ultraviolet light emitted by the gas discharge lamp 1 reaching the light-emitting diode 2. In the example of FIG. 1A, the means for reducing ultraviolet light comprises an ultraviolet-absorbing or ultraviolet-reflecting shielding means 3 provided between the gas discharge lamp 1 and the light-emitting diode 2. Alternatively, the means for reducing ultraviolet light comprises an ultraviolet-absorbing material provided directly on the light-emitting diode 2 and/or on the gas discharge lamp 1.

The side-emitting LED 2 as shown in FIG. 1B is mounted on a printed-circuit board 20, which also functions as heat sink for dissipating heat generated by the LED. The shape of the LED 2 is adapted to emit the beam of light in a generally radial direction out of the radiation-emitting surfaces 12 that extend 360° around a central axis 25. In a preferred embodiment little or no light escapes out of the LED 2 in a direction parallel to the central axis 25. Two leads 23 provide electrical connection between a (DC) power supply and the LED chip. In the example of FIG. 1B, the means for reducing ultraviolet light comprises an ultraviolet-absorbing or ultraviolet-reflecting shielding means 3 provided on top of the LED 2.

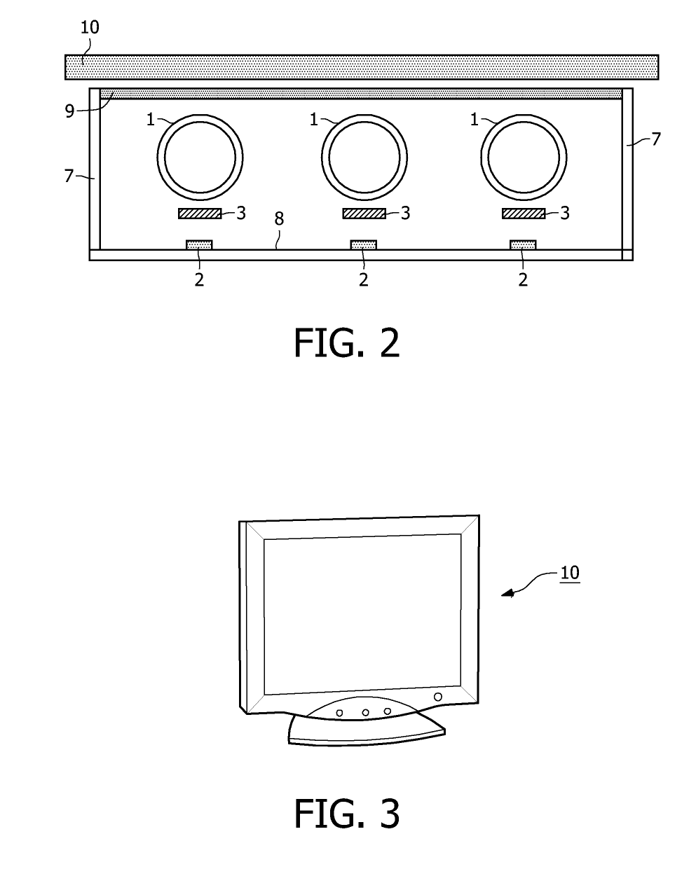

FIG. 2 very schematically shows a cross-sectional view of a second embodiment of the illumination system according to the invention. In the illumination system as shown in FIG. 2, light is generated via a plurality of fluorescent lamps 1 together with a plurality of LEDs 2. The fluorescent lamps 1 and the LEDs 2 are arranged in a light-mixing chamber with (reflective) walls 7, 8 and a light-egress window 9. The illumination system illuminates a display device 10 (see FIG. 3) via the light-egress window 9. The fluorescent lamps 1 comprise a discharge vessel provided with a luminescent layer arranged on an inner wall of the discharge vessel (not shown in FIG. 2). By generating a discharge in the discharge vessel, the mercury vapor inside the discharge vessel emits ultraviolet light (not shown). The ultraviolet light is largely absorbed by the luminescent layer and converted into visible light of a predefined color. The combination of the luminescent materials determines the pre-determined color of the fluorescent lamps 1.

In the example of FIG. 2, the means for reducing UV light comprises an ultraviolet-absorbing or ultraviolet-reflecting shielding means 3 provided between the fluorescent lamps 1 and the light-emitting diode 2. Alternatively, the means for reducing ultraviolet light comprises an ultraviolet-absorbing material provided on the light-emitting diode and/or on the gas discharge lamp. Suitable materials are, for instance, paint, metals, UV-blocking glass or UV-blocking plastic film.

The means for reducing ultraviolet light emitted by the gas discharge lamp reaching the light-emitting diode can also be incorporated in the LED. In a preferred embodiment of the illumination system the light-emitting diode comprises a lens and/or an optoelectronic encapsulant having an improved resistance to ultraviolet light, the means for reducing ultraviolet light being the lens and/or the optoelectronic encapsulant. Suitable materials for encapsulating the LED exhibiting improved UV resistance are, for instance, inorganic or hybrid materials (organic/inorganic) containing UV-blocking particles. Suitable UV-blocking particles are, for instance, TiO₂, CeO₂, and ZnO. Ultra fine titanium dioxide and zinc oxide are well known as physical blockers. These UV-blocking particles are chemically inert, and absorb and/or reflect the full UV spectrum. In addition, also silica works as UV-blocking material. Organic polymers are also suitable materials for encapsulating the LED. A suitable UV-absorbing material is oxybenzone with a broad-spectrum absorber, particularly suitable for augmenting UV-B protection. Another suitable organic polymer is menthyl anthranilate. Anthranilates are weak UV-B filters, and absorb mainly in the near UV-A portion of the spectrum. Yet another suitable organic polymer is avobenzone. Butyl methoxydibenzoylmethane (Parsol 1789) provides superior protection through a larger portion of the UV-A range. Other suitable materials for encapsulating the LED, are ethylhexyl-p-methoxycinnamate and benzophenone, either alone, as a mixture, or in combination with titanium dioxide.

The illumination system as shown in FIG. 2 is very suitable to be used as a so-called scanning backlight system. In particular, by combining fluorescent lamps and LEDs in a backlighting system it is advantageous to operate the fluorescent lamps in a so-called “scanning” mode of operation while the plurality of LEDs are used in a continuous mode of operation. For instance, fluorescent lamps can be employed with a suitable mix of fluorescent material to obtain a color point in the green-blue while the LEDs have a color point in the red. Because the sensitivity of the human eye for the primary color red is relatively low, the impact on the reproduction of motion of an LCD when the LEDs are driven in a continuous mode of operation and the fluorescent lamps are driven in a scanning mode of operation compared to driving all colors in scanning mode of operation is expected to be minor.

FIG. 3 is a display system, in particular a LCD display system.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. An illumination system comprising a gas discharge lamp (1) and at least one light-emitting diode (2),
the illumination system comprising means for reducing ultraviolet light emitted by the gas discharge lamp (1) reaching the light-emitting diode (2).

2. An illumination system as claimed in claim 1, wherein the means for reducing ultraviolet light comprises an ultraviolet-absorbing or ultraviolet-reflecting shielding means (3) provided between the gas discharge lamp (1) and the light-emitting diode (2).

3. An illumination system as claimed in claim 1, wherein the means for reducing ultraviolet light comprises an ultraviolet-absorbing material provided on the light-emitting diode (2) and/or on the gas discharge lamp (1).

4. An illumination system as claimed in claim 1, wherein the light-emitting diode (2) comprises a lens and/or an optoelectronic encapsulant having an improved resistance to ultraviolet light, the means for reducing ultraviolet light being the lens and/or the optoelectronic encapsulant.

5. An illumination system as claimed in claim 1, wherein the illumination system is in a first mode of operation when the gas discharge lamp (1) is operative and in a second mode of operation when the light-emitting diode (2) is operative.

6. An illumination system as claimed in claim 5, wherein, when a power failure occurs while the illumination system lamp operates in the first mode of operation, a switching means causes the illumination system to operate in the second mode of operation.

7. An illumination system as claimed in claim 5, wherein the light-emitting diode (2) operates on a DC power supply, the DC power supply charging while the illumination system operates in the first mode of operation.

8. An illumination system as claimed in claim 7, wherein the DC power supply is a battery.

9. An illumination system as claimed in claim 1, wherein the gas-discharge lamp is a fluorescent lamp.

10. An illumination system as claimed in claim 9, wherein the fluorescent lamp is a low-pressure mercury-vapor discharge lamp.

11. Display device (10) comprising an illumination system as claimed in claim 1.

12. Liquid-crystal display device comprising an illumination system as claimed in claim 1.
